(19) United States
(12) Patent Application Publication
(10) Pub. No.: US 2026/0208724 A1
(43) Pub. Date: Jul. 23, 2026

(54) FASTENING ABNORMALITY DETERMINATION DEVICE AND VEHICLE

(71) Applicant: TOYOTA JIDOSHA KABUSHIKI KAISHA, Toyota-shi (JP)

(72) Inventor: Kazunori HASHIMOTO, Toyota-shi (JP)

(73) Assignee: TOYOTA JIDOSHA KABUSHIKI KAISHA, Toyota-shi (JP)

(21) Appl. No.: 19/405,608

(22) Filed: Dec. 2, 2025

(30) Foreign Application Priority Data
Jan. 17, 2025 (JP) 2025-006522

(51) Int. Cl. B60W 20/50; B60K 6/28; B60W 10/06; B60W 10/08; G01R 31/382; B60K 6/24; B60K 6/26

(52) U.S. Cl. CPC B60W 20/50; B60K 6/28; B60W 10/06; B60W 10/08; G01R 31/382; B60K 6/24; B60K 6/26; B60W 2710/06; B60W 2710/08; B60Y 2200/92

(57) ABSTRACT

A fastening abnormality determination device includes a storage device that stores a trained model. The trained model has been trained by machine learning such that, when it receives predetermined input information as an input, it outputs output information indicating whether loosening has occurred in a fastening structure. The input information includes waveform data representing a waveform of current flowing through the fastening structure. The fastening abnormality determination device is configured to acquire the waveform data by a current sensor, input the acquired waveform data into the trained model, and determine whether loosening has occurred in the fastening structure based on the output information from the trained model.

### CROSS-REFERENCE TO RELATED APPLICATION

This application claims priority to Japanese Patent Application No. 2025-006522 filed on January 17, 2025. The disclosure of the above-identified application, including the specification, drawings, and claims, is incorporated by reference herein in its entirety.

### BACKGROUND

### 1. Technical Field

The present disclosure relates to fastening abnormality determination devices and vehicles.

### 2. Description of Related Art

Japanese Unexamined Patent Application Publication No. 2019-132608 (JP 2019-132608 A) discloses a technique for detecting loosening of a fastening portion when the number of times the variation in electrical resistance of the fastening portion, acquired periodically, exceeds a first threshold is greater than a second threshold. The fastening portion is a portion where a busbar is fastened to an external terminal of a battery. The electrical resistance of the fastening portion is calculated based on the current value (cell current value) of the fastening portion.

### SUMMARY

In the above technique, whether loosening has occurred in the fastening portion (fastening structure) is determined based on the number of times the variation in electrical resistance of the fastening portion exceeds a threshold. However, in a configuration where the cell current value is controlled to follow a varying target value, depending on how the target value changes, the number of times the variation in electrical resistance of the fastening portion exceeds the threshold may increase even when no loosening has occurred. In the above technique, erroneous determinations are likely to occur under certain conditions.

The present disclosure has been made to address the above issue, and an object thereof is to provide a fastening abnormality determination device and a vehicle capable of accurately determining whether loosening has occurred in a fastening structure.

One aspect of the present disclosure provides a fastening abnormality determination device described below. The fastening abnormality determination device is configured to determine whether loosening has occurred in a fastening structure provided by fastening, with a fastening component, a plurality of components to be fastened. The fastening abnormality determination device includes a storage device that stores a trained model. The trained model has been trained by machine learning such that, when it receives predetermined input information as an input, it outputs output information indicating whether loosening has occurred in the fastening structure. The input information includes waveform data representing a waveform of current flowing through the fastening structure. The fastening abnormality determination device is configured to acquire the waveform data by a current sensor, input the acquired waveform data into the trained model, and determine whether loosening has occurred in the fastening structure based on the output information from the trained model.

The present disclosure can thus provide a fastening abnormality determination device and a vehicle capable of accurately determining whether loosening has occurred in a fastening structure.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram showing a schematic configuration of a vehicle according to an embodiment of the present disclosure;

FIG. 2 is a diagram showing the configuration of a fastening abnormality determination device according to the embodiment;

FIG. 3 shows timing charts illustrating training images used in first training;

FIG. 4 shows timing charts illustrating training images used in second training;

FIG. 5 is a flowchart of a method for determining loosening according to the embodiment; and

FIG. 6 is a flowchart of a modification of the process flow shown in FIG. 5.

### DETAILED DESCRIPTION OF EMBODIMENTS

An embodiment of the present disclosure will now be described in detail with reference to the drawings. The same or corresponding portions are denoted by the same signs throughout the drawings, and description thereof will not be repeated. In the figures, the three mutually orthogonal axes (X, Y, and Z) are defined such that the direction indicated by the arrow is "+" and the opposite direction is "−."

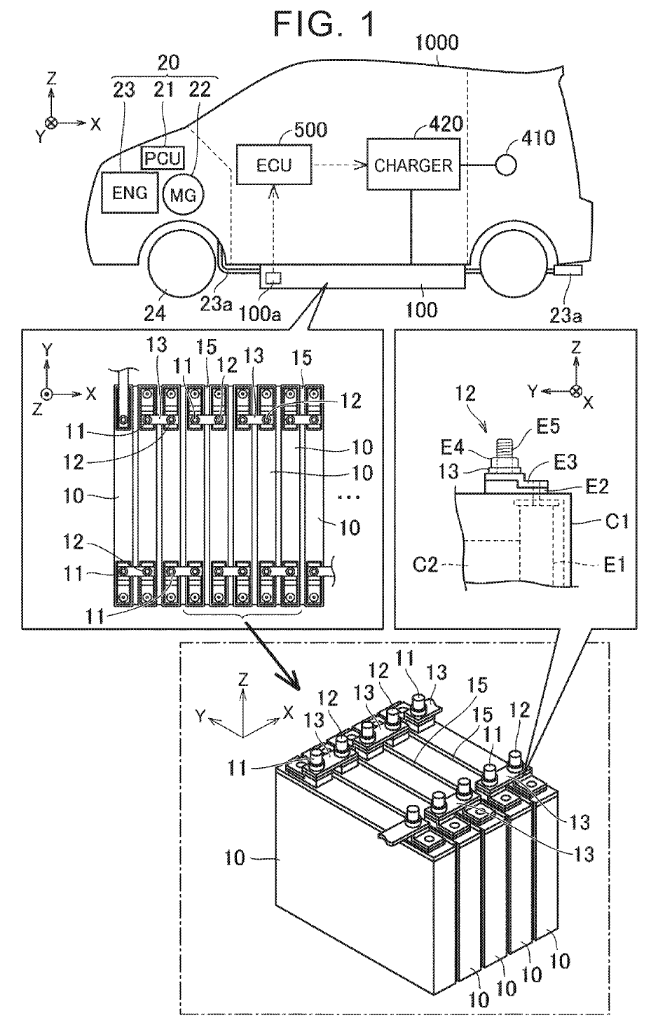

FIG. 1 shows the configuration of a vehicle according to the present embodiment. In FIG. 1, the −X-direction corresponds to the direction of travel of the vehicle, and the −Z-direction corresponds to the vertical direction (the direction of gravity). Referring to FIG. 1, a vehicle 1000 includes a battery pack 100. For example, the battery pack 100 is fixed below the floor of the vehicle 1000. However, the battery pack 100 may be mounted in any manner.

The vehicle 1000 further includes a drive system 20 that drives the vehicle 1000, an inlet 410 and a charger 420 (on-board charger) that are used for charging the battery pack 100, and an electronic control unit (ECU) 500.

The drive system 20 includes a power control unit (PCU) 21, a motor generator (MG) 22, and an engine 23. The vehicle 1000 is configured to travel using electric power output from the battery pack 100. The vehicle 1000 is, for example, a plug-in hybrid electric vehicle (PHEV). However, the vehicle 1000 may be another type of electrified vehicle (xEV) such as a battery electric vehicle (BEV).

The PCU 21 includes, for example, an inverter. The MG 22 functions as a traction motor and rotates drive wheels 24 of the vehicle 1000. The MG 22 drives the vehicle 1000 using electric power output from the cells in the battery pack 100. Specifically, the PCU 21 drives the MG 22 using electric power supplied from the battery pack 100. As a result, the MG 22 enters a motoring state. In the motoring state, the MG 22 converts electric power into torque. The torque is transmitted to the drive wheels 24. For example, when the vehicle 1000 decelerates, the MG 22 enters a regenerative state, and charges the cells in the battery pack 100 through regenerative power generation.

The engine 23 functions as an internal combustion engine and drives the vehicle 1000 using combustion energy of fuel. Specifically, the engine 23 generates power from the combustion energy of fuel supplied from a fuel tank (not shown). The generated power is transmitted to the drive wheels 24. An exhaust pipe 23a is connected to the engine 23 and discharges exhaust gases from the engine 23 to the outside of the vehicle.

The battery pack 100 includes a plurality of cells 10 (energy storage cells), each functioning as a secondary cell. In the present embodiment, liquid lithium-ion cells are employed as the cells 10. However, the cells 10 are not limited to lithium-ion cells and may be other types of secondary cells such as nickel metal hydride cells or sodium-ion cells. The secondary cells are not limited to liquid secondary cells and may be all-solid-state secondary cells.

Each of the cells 10 includes an anode terminal 11 and a cathode terminal 12. The cells 10 are stacked in, for example, the X direction and constrained to form a battery stack. The battery stack is an energy storage module in which the cells 10 electrically connected to each other are modularized. Specifically, a spacer 15 is provided between adjacent cells 10 in the X-direction. The spacer 15 may function as a cooler that cools the two cells 10 located on both sides (+X side and −X side) thereof. The cells 10 are alternately oriented in the X-direction and electrically connected in series. The anode terminal 11 of one cell 10 and the cathode terminal 12 of its adjacent cell 10 are electrically connected via a conductive member 13 (e.g., a busbar). More specifically, as described below, these terminals of the cells are fastened to the conductive member 13.

Each cell 10 includes a metal case C1. An electrode assembly C2 and an electrolyte solution that constitute a lithium-ion cell are housed inside the case C1. The cathode terminal 12 includes a current collector terminal E1, a gasket E2, and a base E3. The current collector terminal E1 is housed inside the case C1. The electrode assembly C2 includes a laminate of a plurality of cathode sheets and a plurality of anode sheets. This laminate is formed by alternately stacking the cathode and anode sheets. Each cathode sheet includes, for example, a cathode current collector and a cathode active material layer. Each anode sheet includes, for example, an anode current collector and an anode active material layer. Each of the cathode and anode sheets may be formed by coating the surface of a metal foil, used as the current collector, with an active material. A separator may be disposed between the cathode and anode sheets. Inside the case C1, the current collector terminal E1 of the cathode terminal 12 is electrically connected to the cathode sheets of the electrode assembly C2.

The gasket E2 is positioned between the case C1 and the base E3. The base E3 may be formed of a metal alloy (for example, an alloy containing at least one of the following metals: aluminum, iron, and copper). The current collector terminal E1 may protrude outward from inside the case C1 so as to pass through the gasket E2 and the base E3. The protruding portion of the current collector terminal E1 may be fixed to the base E3 by being crimped onto the upper surface (+Z-side surface) of the base E3.

The cathode terminal 12 is provided with a nut E4 and a bolt E5. The nut E4 and the bolt E5 are fastening components configured to fasten the base E3 of the cathode terminal 12 to the conductive member 13. The conductive member 13 may be a metal plate. The bolt E5 includes a head embedded in the gasket E2 and a threaded portion with external threads. In the cell 10, the internal threads of the nut E4 and the external threads of the bolt E5 are screwed together, thereby fastening the base E3 of the cathode terminal 12 to the conductive member 13. A fastening structure (the fastening portion of the cell 10) is formed by fastening a plurality of components to be fastened (the base E3 and the conductive member 13) together using a fastening component (the nut E4 and the bolt E5).

The anode terminal 11 has basically the same configuration as the cathode terminal 12. However, since the polarities of the anode terminal 11 and the cathode terminal 12 are opposite, appropriate materials are selected for each terminal. Inside the case C1, the current collector terminal of the anode terminal 11 is electrically connected to the anode sheets of the electrode assembly C2. The potentials of the anode and cathode sheets of the electrode assembly C2 are output to the anode terminal 11 and cathode terminal 12 (external terminals), respectively.

As described above, a plurality of fastening portions (one for each terminal) is formed in the battery stack of the battery pack 100. The number of cells 10 can be set to any value according to desired specifications (e.g., output power). The battery stack may be composed entirely of the same type of cells, or may include different types of cells. The electrode assembly C2 is not limited to a laminate in which a plurality of electrode sheets is stacked in one direction, and may be a wound roll (e.g., a wound roll of a laminate in which cathode and anode sheets are alternately arranged). The case C1 may be provided with a gas release valve.

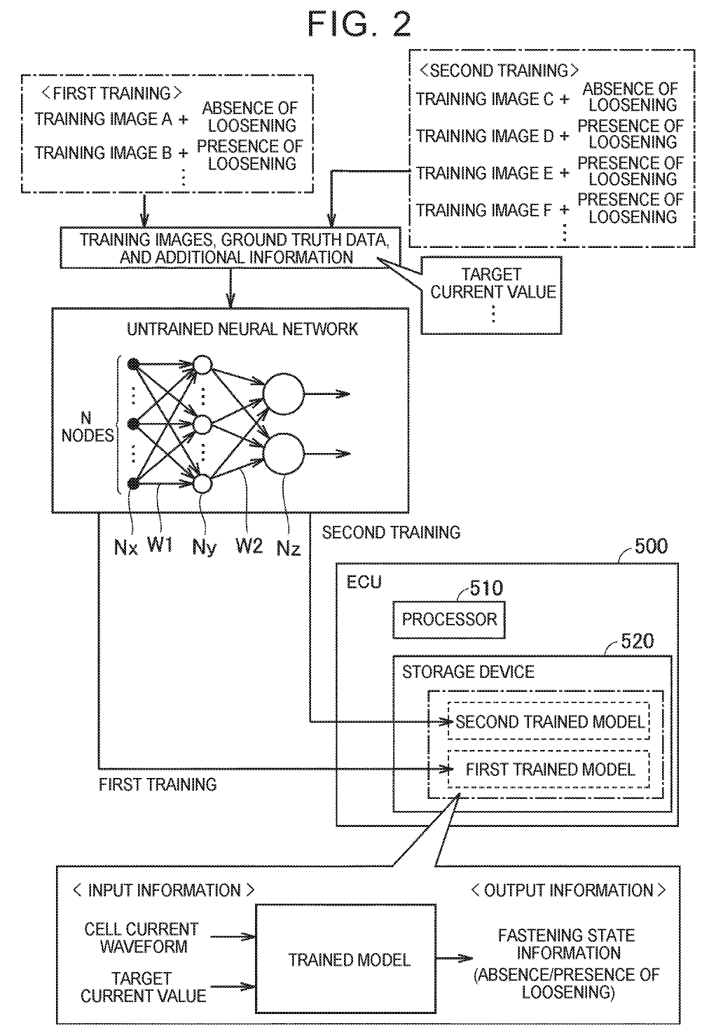

FIG. 2 shows the configuration of the ECU 500. Referring to FIG. 2, the ECU 500 includes a processor 510 and a storage device 520. The storage device 520 is configured to retain stored information. In the ECU 500, the processor 510 executes programs stored in the storage device to perform various types of control. In addition to the programs, the storage device 520 stores various types of information used by the programs. Specifically, the storage device 520 stores a first trained model and a second trained model respectively generated through first training and second training described below.

In the present embodiment, separate untrained neural networks are prepared for the first training and the second training. For example, an untrained neural network can be trained using supervised machine learning to obtain a trained neural network (trained model). In the present embodiment, the untrained neural network employs a general-purpose machine learning algorithm. The trained model functions as a model for determining whether loosening has occurred in fastening portions of the battery stack.

A neural network includes an input layer Nx, a hidden layer Ny, and an output layer Nz. A training image is fed into the input layer Nx. The input layer Nx may include N nodes corresponding to the number of pixels in the training image. The number of nodes in the output layer Nz is, for example, two. One of the two nodes outputs the probability (low: 0, high: 1) that the waveform corresponds to the presence of loosening, while the other outputs the probability (low: 0, high: 1) that the waveform corresponds to the absence of loosening. However, the number of nodes in the output layer Nz is not limited to two and may be set to any value, including one.

In the present embodiment, an untrained neural network was trained by supervised machine learning using the following training data: training images representing the waveform of the current flowing through the cell 10 (hereinafter referred to as "cell current waveform") in a predetermined graph format and image format, ground truth data, and additional information. A training image is data representing the numerical value (pixel value) of each pixel in an image depicting a current waveform within a region with a predetermined number of pixels. This region in which the current waveform is drawn is hereinafter also referred to as "image region." The number of pixels in the image region can be set to any value. In one example, the image region has about 60 pixels vertically and about 200 pixels horizontally. Each pixel value in the image region takes either 0 (white) or 1 (black). The grand truth data indicates the presence or absence of loosening. In the present embodiment, the target value of the current flowing through the cell 10 (hereinafter referred simply as "target current value") is employed as the additional information.

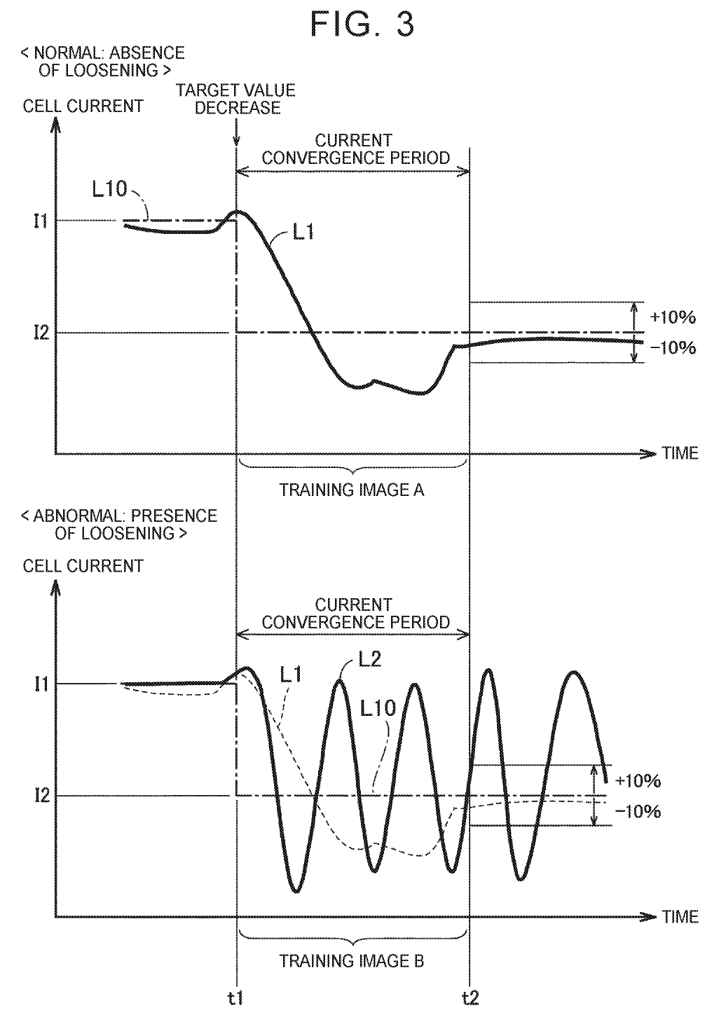

FIG. 3 shows timing charts illustrating training images used in the first training. In FIG. 3, lines L1, L2 respectively show data in normal and abnormal states. In the normal state, no fastening portion in the battery stack described above is loosened. In the abnormal state, at least one fastening portion in the battery stack is loosened. Each of lines L1, L2 shows how the cell current (the current of the cell 10) changes over time. Line L10 shows how the target current value changes over time. In the timing charts, "t" denotes time.

In the example shown in FIG. 3, at t1, the target current value decreases from a first target value (hereinafter, "I1") to a second target value (hereinafter, "I2") that is smaller than I1. I1 corresponds to the target current value before the decrease, and I2 corresponds to the current target value after the decrease. The period from t1 to t2 corresponds to the current convergence period. The current convergence period starts when the target current value is changed. The length of the current convergence period corresponds to the time it takes for the cell current to converge after the target current value has been changed (increased or decreased). For example, the length of the current convergence period is determined in advance through experiments for both increases and decreases of the target current value, and stored in the storage device 520. In one example, the current convergence period for a decrease in the target current value was two seconds.

As shown by line L1, in the normal state, the cell current converges within ±10% of the target current value by the time the current convergence period (period from t1 to t2) has elapsed. Thus, when the target current value is changed in the normal state, the cell current varies so as to approach the target current value, and converges within a range close to the new target current value. By contrast, as shown by line L2, in the abnormal state, the cell current does not converge within ±10% of the target current value even after the current convergence period (period from t1 to t2) has elapsed. As shown by lines L1, L2, the cell current waveform during the period from t1 to t2 differs between the normal and abnormal states.

A first dataset and a second dataset used in the first training can be obtained from the measured data shown in FIG. 3. The first dataset includes training image A, I1, I2, and ground truth data indicating the absence of loosening. Training image A, represented in the image format described above, shows the portion of the cell current waveform indicated by line L1 during the period from t1 to t2. The second dataset includes training image B, I1, I2, and ground truth data indicating the presence of loosening. Training image B, represented in the image format described above, shows the portion of the cell current waveform indicated by line L2 during the period from t1 to t2. In the present embodiment, additional measurements of cell current waveforms during the current convergence period are taken in the same manner as the example shown in FIG. 3. In this way, a desired number of datasets for both the normal state and the abnormal state are obtained, and the neural network undergoes the first training using the obtained datasets. As a result, the first trained model with high determination accuracy is generated.

Specifically, the ECU 500 controls the cell current to follow the varying target current value. When the target current value decreases, the cell current first falls below the target current value (undershoot) and then rises toward the target current value. Accordingly, the cell current value tends to oscillate. In a method in which loosening is detected based on whether the cell current value exceeds a threshold, erroneous determinations are likely to occur in the normal state due to such oscillations in the cell current value. By contrast, the first trained model determines the presence or absence of loosening based on the shape formed by the cell current values (i.e., the cell current waveform). This suppresses erroneous determinations caused by oscillations in the cell current value in the normal state. As shown in FIG. 3, the cell current waveform during the current convergence period differs between the normal and abnormal states. Accordingly, the first trained model trained by machine learning as described above can determine the presence or absence of loosening at an early stage and with high accuracy.

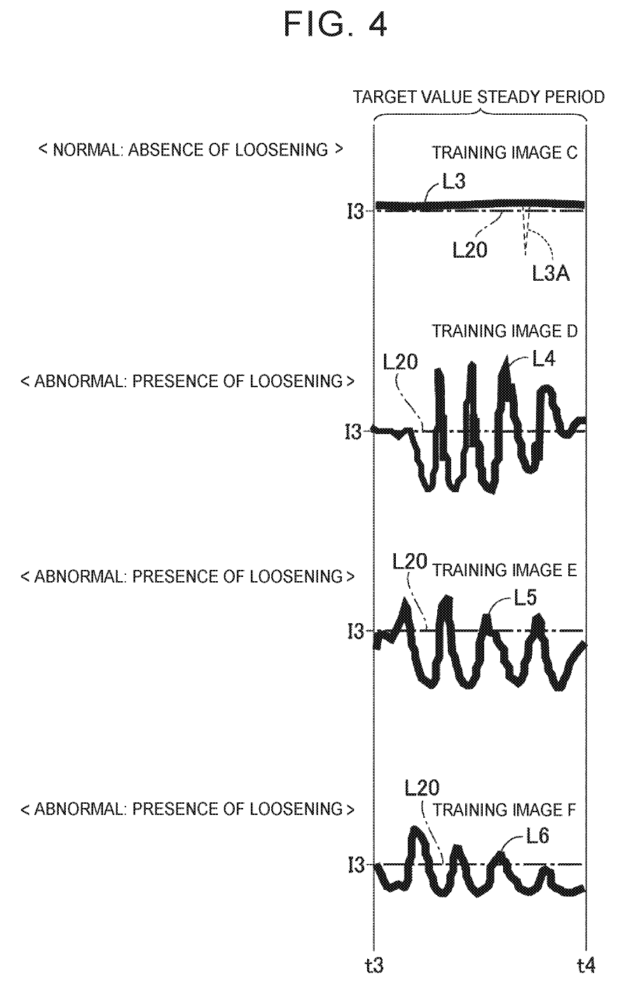

FIG. 4 shows timing charts illustrating training images used in the second training. In FIG. 4, line L3 shows data in the normal state. Each of lines L4 to L6 shows data in the abnormal state. Each of lines L3 to L6 shows how the cell current (the current of the cell 10) changes over time. Line L20 shows how the target current value changes over time.

In the example shown in FIG. 4, the period from t3 to t4 corresponds to a target value steady period. The target current value remains constant during the target value steady period. When the target current value is changed, the target value steady period begins once the time it takes for the cell current to converge after the change of the target current value has elapsed. For example, in the timing charts shown in FIG. 3, the period after t2 corresponds to the target value steady period. A portion of the target value steady period is extracted and set as the period from t3 to t4.

As shown by line L20, during the period from t3 to t4, the target current value is kept at a third target value (hereinafter "I3"). As shown by line L3, in the normal state, the cell current during the target value steady period (period from t3 to t4) hardly fluctuates and follows the target current value. By contrast, as shown by lines L4 to L6, in the abnormal state, the cell current fluctuates violently. Such fluctuations are considered to be current fluctuations caused by movement of the conductive member 13 (busbar) when loosening occurs. The cell current waveform during the period from t3 to t4 differs between the normal and abnormal states. The length of the period from t3 to t4 may be the same as the length of the period from t1 to t2 shown in FIG. 3.

Third to sixth datasets used in the second training can be obtained from the measured data shown in FIG. 4. The third dataset includes training image C, I3, and ground truth data indicating the absence of loosening. Training image C, represented in the image format described above, shows the cell current waveform during the target value steady period shown by line L3. The fourth dataset includes training image D, I3, and ground truth data indicating the presence of loosening. Training image D, represented in the image format described above, shows the cell current waveform during the target value steady period shown by line L4. The fifth dataset includes training image E, I3, and ground truth data indicating the presence of loosening. Training image E, represented in the image format described above, shows the cell current waveform during the target value steady period shown by line L5. The sixth dataset includes training image F, I3, and ground truth data indicating the presence of loosening. Training image F, represented in the image format described above, shows the cell current waveform during the target value steady period shown by line L6. In the present embodiment, additional measurements of cell current waveforms during the target value steady period are taken in the same manner as the example shown in FIG. 4. In this way, a desired number of datasets for both the normal state and the abnormal state are obtained, and the neural network undergoes the second training using the obtained datasets. As a result, the second trained model with high determination accuracy is generated.

Specifically, depending on the conditions of the vehicle 1000 (including the road surface condition), the cell current may momentarily exhibit an abnormal value even in the normal state, as indicated by dashed line L3A in FIG. 4. In a method in which loosening is detected based on whether the cell current value exceeds a threshold, erroneous determinations are likely to occur in the normal state due to such momentary abnormal values. By contrast, the second trained model determines the presence or absence of loosening based on the shape formed by the cell current values (i.e., the cell current waveform). This suppresses erroneous determinations caused by momentary abnormal values in the normal state. As shown in FIG. 4, the cell current waveform during the target value steady period differs between the normal and abnormal states. Accordingly, the second trained model trained by machine learning as described above can determine the presence or absence of loosening at an early stage and with high accuracy.

As described above, the first trained model and the second trained model are generated by the first training and the second training, respectively. Through supervised machine learning (for example, training on the shape of the cell current waveform), the weight W1 between the input layer Nx and the hidden layer Ny and the weight W2 between the hidden layer Ny and the output layer Nz are adjusted such that the target output of the neural network matches the actual output. By repeatedly adjusting the weights W1, W2 based on the supervisory signal, the determination accuracy of the neural network can be improved. The generated first and second trained models are stored in the storage device 520, as shown in FIG. 2.

The first trained model is configured such that, when it receives, as inputs, (i) a cell current waveform during the current convergence period represented in the image format described above (hereinafter referred to as "first current waveform image"), (ii) the target current value before the decrease, and (iii) the target current value after the decrease, it outputs information indicating whether at least one fastening portion in the battery stack is loosened (hereinafter referred to as "fastening state information"). The second trained model is configured such that, when it receives, as inputs, (i) a cell current waveform during the target value steady period represented in the image format described above (hereinafter referred to as "second current waveform image") and (ii) the target current value during the target value steady period, it outputs fastening state information. For example, each of the first and second trained models may, depending on the determination result, output to the output layer Nz either fastening state information "0, 1" indicating the absence of loosening or fastening state information "1, 0" indicating the presence of loosening. Each of the first and second trained models may output "0, 0" or "1, 1" to the output layer Nz in cases where a determination is not possible (i.e., the presence or absence of loosening cannot be determined with sufficient accuracy). With such a configuration, the determination accuracy of each trained model can be more easily improved. However, the present disclosure is not limited to this. For example, in a configuration in which the output layer Nz has a single node, training of the neural network (first training and second training) may be performed such that the output layer Nz outputs "0" when there is no loosening and "1" when loosening occurs.

The vehicle 1000 shown in FIG. 1 is configured to travel in one drive mode selected from among a plurality of drive modes. For example, the vehicle 1000 may be configured to travel in a first drive mode in which the vehicle is driven by the MG 22 (motor), a second drive mode in which the vehicle is driven by both the MG 22 and the engine 23, and a third drive mode in which the vehicle is driven by the engine 23. The ECU 500 may switch among the first to third drive modes according to the conditions of the vehicle 1000.

The vehicle 1000 is also configured to perform external charging of the battery pack 100 (charging using power supplied from outside the vehicle) while parked. The inlet 410 is configured to be connected to a charging cable of power supply equipment installed outside the vehicle. The charger 420 performs AC to DC conversion. During external charging, with alternating current power being input to the charger 420 from outside the vehicle via the inlet 410, the ECU 500 controls the charger 420. The charger 420 converts the alternating current power into direct current power according to a control command from the ECU 500 and outputs the direct current power to the battery pack 100. In this way, each cell contained in the battery pack 100 is charged.

The vehicle 1000 further includes various sensors that detect the state of the vehicle 1000 in real time (such as position sensor, outside air temperature sensor, vehicle speed sensor, odometer, engine state sensor, and monitoring unit 100a). The engine state sensor includes various sensors that detect the state of the engine 23 (for example, intake air amount, intake pressure, exhaust pressure, engine speed, and engine coolant temperature) in real time. The monitoring unit 100a is disposed in, for example, the battery pack 100. The monitoring unit 100a includes various sensors that detect the states of the respective cells 10 (for example, voltage, current, and temperature). The monitoring unit 100a and the ECU 500 may function as a battery management system (BMS). In the present embodiment, all the cells 10 contained in the battery pack 100 are connected in series, and the same magnitude of current flows through all the cells 10. Accordingly, a single current sensor may be shared by all the cells 10. However, the present disclosure is not limited to this, and the battery pack 100 may include multiple cells connected in parallel. A current sensor may be provided for each cell 10.

The ECU 500 sequentially determines the target current value based on at least one of the following: requests related to driving of the vehicle 1000 (for example, requests for acceleration, deceleration, or steering from a user or an autonomous driving system); requests related to external charging of the battery pack 100 (for example, requests from external power supply equipment); and the state of the vehicle 1000 detected by the sensors described above. The ECU 500 then performs charge/discharge control of each cell 10 such that the cell current approaches the determined target current value.

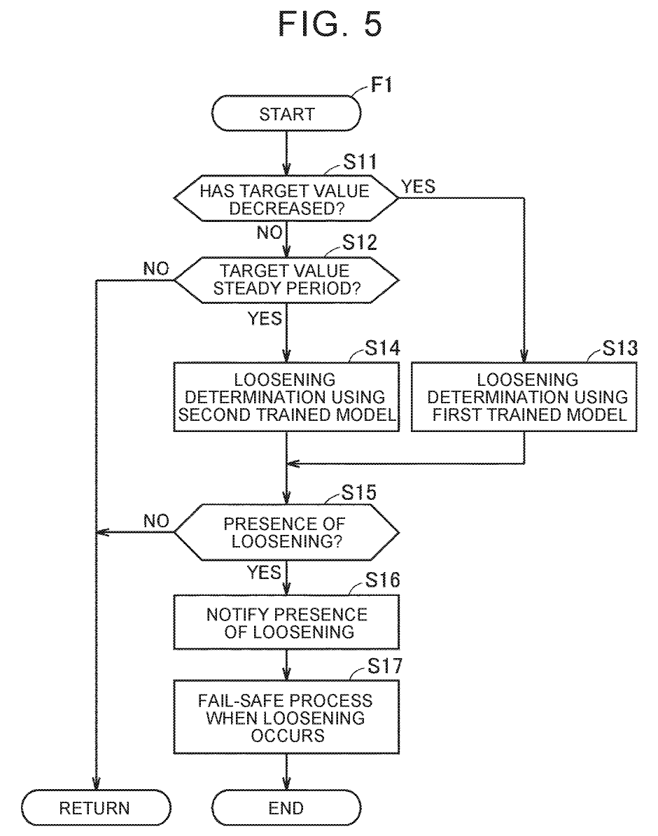

FIG. 5 is a flowchart of a process related to loosening determination by the ECU 500. The process flow F1 shown in FIG. 5 is repeatedly executed by the ECU 500. In the flowchart, "S" denotes a step.

In the process flow F1, the ECU 500 determines in S11 whether the target current value has decreased. The ECU 500 may determine that the target current value has decreased when predetermined control for decreasing the target current value has been performed. In the present embodiment, when the drive mode is switched from the first drive mode to the second drive mode, a YES determination is made in S11. In addition, when a charging restriction for protecting the cell 10 is applied during external charging, a YES determination is made in S11. The ECU 500 may determine whether the target current value has decreased based on whether the previous target current value minus the current target current value exceeds a predetermined value. In the present embodiment, even when the previous target current value (the target current value before the decrease) is greater than the current target current value (the target current value after the decrease), a NO determination is made in S11 when the difference between the two (the degree of decrease) is small.

When it is determined that the target current value has decreased (YES in S11), the ECU 500 performs loosening determination in S13 using the first trained model. Specifically, the ECU 500 acquires a first current waveform image. The cell current waveform during the current convergence period is detected by the current sensor included in the monitoring unit 100a. The processor 510 of the ECU 500 inputs the acquired first current waveform image, the target current value before the decrease, and the target current value after the decrease into the first trained model. In this way, fastening state information is output from the first trained model. The process then proceeds to S15.

In S15, the ECU 500 determines whether the obtained fastening state information indicates the presence of loosening. When the fastening state information indicates the presence of loosening (YES in S15), the ECU 500 notifies the user in S16 that an abnormality (specifically, loosening) has occurred in the battery pack 100. The ECU 500 may send a notification of the abnormality in the battery pack 100 to a user terminal (for example, an in-vehicle terminal or a mobile terminal). Upon receiving the notification, the user terminal may display a message informing the user of the abnormality in the battery pack 100. In the subsequent step S17, the ECU 500 executes a predetermined fail-safe process. The ECU 500 stores, in the storage device 520, information indicating that loosening has occurred in the battery pack 100. The ECU 500 also switches a relay (not shown) provided in an input/output portion of the battery pack 100 to a disconnected state (open state), thereby shutting off input and output power of the battery pack 100. When the vehicle 1000 is traveling in the first or second drive mode, the ECU 500 switches to the third drive mode such that the vehicle 1000 continues to travel while being driven by the engine 23. When the vehicle 1000 is traveling in the third drive mode, the ECU 500 allows the vehicle 1000 to continue traveling in that mode. When the vehicle 1000 is undergoing external charging of the battery pack 100, the ECU 500 notifies the power supply equipment to stop external charging, and also stops external charging of the battery pack 100. The ECU 500 then prohibits future operation in the first and second drive modes and external charging. Once S17 is completed, the process flow F1 ends.

On the other hand, when the fastening state information indicates the absence of loosening or indicates that determination is not possible (NO in S15), the process returns to the first step (S11). When it is determined that the target current value has not decreased (NO in S11), the ECU 500 determines in S12 whether the target value steady period has begun. The ECU 500 may determine whether the target value steady period has begun, based on whether the current convergence period has elapsed since the most recent change in the target current value. In the present embodiment, when a YES determination was made in S11 and the current convergence period related to the decrease of the target current value has elapsed, a YES determination is made in S12. The ECU 500 may determine that the target value steady period has begun when the target current value has remained unchanged for a predetermined period of time.

When it is determined that the target value steady period has not begun (NO in S12), the process returns to S11. On the other hand, when it is determined that the target value steady period has begun (YES in S12), the ECU 500 performs loosening determination in S14 using the second trained model. Specifically, the ECU 500 acquires a second current waveform image. The cell current waveform during the target value steady period is detected by the current sensor included in the monitoring unit 100a. The processor 510 of the ECU 500 inputs the acquired second current waveform image and the target current value (constant value) during the target value steady period into the second trained model. In this way, fastening state information is output from the second trained model. The process then proceeds to S15. In S15, the presence or absence of an abnormality (loosening) is determined based on the fastening state information output from the second trained model. When it is determined that an abnormality is present, S16 and S17 are executed.

As described above, the ECU 500 (fastening abnormality determination device) according to the present embodiment includes the storage device 520 that stores the first trained model and the second trained model. Each of the first and second trained models has been trained by machine learning such that, when it receives predetermined input information as an input, it outputs output information indicating whether loosening has occurred in the fastening structure. The input information includes waveform data (the first current waveform image and the second current waveform image) representing the waveform of the current flowing through the fastening structure. The ECU 500 is configured to acquire waveform data using a current sensor (the monitoring unit 100a), input input information including the acquired waveform data into a trained model (the first or second trained model), and determine, based on the output information from the trained model to which the input information has been input, whether loosening has occurred in the fastening structure (the fastening portion of the cell 10). This fastening abnormality determination device can accurately determine whether loosening has occurred in the fastening structure by using the trained models described above.

In the embodiment described above, the first trained model is acquired by performing the first training on one untrained neural network, and the second trained model is obtained by performing the second training on another untrained neural network. In both the first and second trained models, the output information is fastening state information. On the other hand, the input information differs between the first trained model and the second trained model. The input information of the first trained model includes the first current waveform image, the target current value before the decrease, and the target current value after the decrease. The input information of the second trained model includes the second current waveform image and the target current value during the target value steady period. The input information and the output information correspond to explanatory variables and target variables, respectively. When the target current value has decreased, the ECU 500 determines, using the first trained model, whether loosening has occurred in the fastening structure (S13 in FIG. 5). When the target current value is constant, the ECU 500 determines, using the second trained model, whether loosening has occurred in the fastening structure (S14 in FIG. 5). With this configuration, efficient training can be achieved using training data tailored to different situations. However, the present disclosure is not limited to this, and a trained model having both the functions of the first and second trained models may be generated by performing both the first training and the second training on a single untrained neural network.

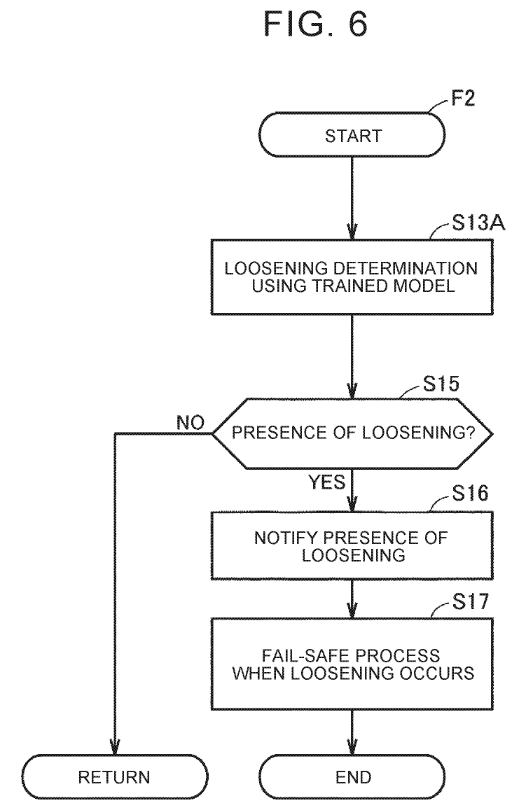

In a modification, supervised machine learning is performed on a neural network using the following data: a training image representing the waveform of the cell current value in a predetermined section, a training image representing the waveform of the target current value in a predetermined section, the moving average of the cell current, the moving average of the target current value, the standard deviation of the cell current, the standard deviation of the target current value, and ground truth data. A trained model generated through such training (hereinafter referred to as the "trained model according to the modification") is stored in the storage device 520 of the ECU 500 in place of the first and second trained models described above. The ECU 500 executes the process flow F2 shown in FIG. 6 instead of the process flow F1 shown in FIG. 5.

FIG. 6 is a flowchart of a modification of the process flow shown in FIG. 5. The process flow F2 is the same as the process flow F1 shown in FIG. 5 except that S13A is employed in place of S11 to S14 (FIG. 5).

In S13A, the ECU 500 performs loosening determination using the trained model according to the modification. Specifically, the ECU 500 acquires the waveform of the cell current value, the waveform of the target current value, the moving average of the cell current, the moving average of the target current value, the standard deviation of the cell current, and the standard deviation of the target current value, all within a predetermined section (for example, the most recent five-second section). The ECU 500 then converts each of the waveform of the cell current value and the waveform of the target current value into an image in a predetermined format. The processor 510 of the ECU 500 inputs, into the trained model according to the modification, the waveform (image) of the cell current value, the waveform (image) of the target current value, the moving average of the cell current, the moving average of the target current value, the standard deviation of the cell current, and the standard deviation of the target current value, all within the predetermined section. In this way, fastening state information is output from the trained model according to the modification. The process then proceeds to S15. In the process flow F2, loosening determination is repeatedly performed regardless of the behavior of the target current value. That is, loosening determination is also performed when the target current value increases. With the trained model according to the modification, it is possible to accurately determine whether loosening has occurred in the fastening structure (the fastening portion of the cell 10).

In the trained model according to the modification, both the moving average and the standard deviation are employed as features (input information) in order to improve determination accuracy. However, the moving average and the standard deviation may not be used as input information, and either or both of the moving average and the standard deviation may be omitted.

Training of the neural network may be performed sequentially by, for example, a server in the cloud. The server may then update the trained model in the ECU 500 via Over-the-Air (OTA). The training method is not limited to supervised machine learning, and may be unsupervised machine learning.

The fastening structure for which the fastening abnormality determination device (ECU 500) determines the presence or absence of loosening is not limited to the fastening portion of the cell (the anode terminal 11, the cathode terminal 12, and the conductive member 13), and may be any structure in which a plurality of components to be fastened is fastened together with a fastening component.

The embodiment disclosed herein should be considered to be illustrative in all respects and not restrictive. The scope of the present disclosure is set forth in the claims rather than in the above description of the embodiment, and is intended to include all modifications within the meaning and scope equivalent to the claims.

What is claimed is:

1. A fastening abnormality determination device configured to determine whether loosening has occurred in a fastening structure provided by fastening, with a fastening component, a plurality of components to be fastened, the fastening abnormality determination device comprising a storage device that stores a trained model trained by machine learning such that, when the trained model receives predetermined input information as an input, the trained model outputs output information indicating whether loosening has occurred in the fastening structure, wherein:
the input information includes waveform data representing a waveform of current flowing through the fastening structure; and
the fastening abnormality determination device is configured to acquire the waveform data by a current sensor, input the acquired waveform data into the trained model, and determine whether loosening has occurred in the fastening structure based on the output information from the trained model.

2. The fastening abnormality determination device according to claim 1, wherein:
the fastening abnormality determination device is configured to control the current flowing through the fastening structure so as to bring the current flowing through the fastening structure closer to a target value; and
the input information further includes the target value.

3. The fastening abnormality determination device according to claim 2, wherein:
the storage device stores, as the trained model, a first trained model and a second trained model; and
the fastening abnormality determination device is configured to
when the target value has decreased, determine, using the first trained model, whether loosening has occurred in the fastening structure, and
when the target value is constant, determine, using the second trained model, whether loosening has occurred in the fastening structure.

4. A vehicle including the fastening abnormality determination device according to claim 1, and the fastening structure, the vehicle comprising:
a motor configured to drive the vehicle using electric power output from a battery mounted on the vehicle; and
an internal combustion engine configured to drive the vehicle using combustion energy of fuel,
wherein the fastening structure is a fastening portion of the battery.

5. The vehicle according to claim 4, wherein the fastening abnormality determination device is configured to, when the fastening abnormality determination device determines, while the vehicle is traveling while being driven by the motor, that loosening has occurred in the fastening structure, switch the vehicle from being driven by the motor to being driven by the internal combustion engine such that the vehicle continues to travel while being driven by the internal combustion engine.
